(19) United States
(12) Patent Application Publication
(10) Pub. No.: US 2011/0237086 A1
(43) Pub. Date: Sep. 29, 2011

(54) TEMPLATE AND METHOD OF MANUFACTURING THE SAME, AND SEMICONDUCTOR DEVICE MANUFACTURING METHOD USING THE TEMPLATE

(76) Inventor: Ikuo YONEDA, Yokohama-Shi (JP)

(21) Appl. No.: 13/024,932

(22) Filed: Feb. 10, 2011

(30) Foreign Application Priority Data
Mar. 23, 2010 (JP) 2010-66517

(51) Int. Cl. H01L 21/31; B32B 3/30; C23F 1/04

(52) U.S. Cl. 438/778; 428/156; 428/157; 216/41; 257/E21.24

(57) ABSTRACT

According to one embodiment, there is provided a template which includes a first region and a second region. The first region is provided with a first pattern of a plurality of recessed portions formed on a main surface of the template, and has a first thickness. The second region is provided with a second pattern of a plurality of recessed portions formed on the main surface of the template, and has a second thickness different from the first thickness. The second pattern is different from the first pattern in at least one of interval and dimension of the recessed portions.

### CROSS-REFERENCE TO RELATED APPLICATIONS

This application is based upon and claims the benefit of priority from the prior Japanese Patent Application No. 2010-66517, filed on Mar. 23, 2010, the entire contents of which are incorporated herein by reference.

### FIELD

Embodiments described herein relate generally to a template and a method of manufacturing the same, and a semiconductor device manufacturing method using the template.

### BACKGROUND

As a conventional technique, there is known a stamper formed in such a manner that the thickness between a pattern formation surface, where a concave/convex pattern is formed, and a back surface gradually decreases toward the outer edge side (e.g., see Japanese Patent Application Laid-Open No. 2007-190735).

With this stamper, a uniform pressure can be applied over a resin layer to which the concave/convex pattern is to be transferred, so that the concave/convex pattern can be transferred to the resin layer with high precision.

In the conventional stamper, however, the thickness gradually decreases toward the outer edge side regardless of the density of the concave/convex pattern. Therefore, regarding a reaction force arising from the flexure of the stamper at the time of separation of the resin layer and the stamper, the reaction force exerted on the stamper increases as the thickness of the stamper decreases. This can cause a defect in the shape of a resist pattern.

### BRIEF DESCRIPTION OF THE DRAWINGS

FIG. 1(a) is a plan view of a template according to an embodiment, and FIG. 1(b) is a cross-sectional view taken along the line I(b)-I(b) of FIG. 1(a);

FIGS. 2(a) through 2(f) are process drawings of a template manufacturing method according to the embodiment;

FIGS. 3(a) through 3(d) are process drawings of a semiconductor device manufacturing method using the template according to the embodiment; and

FIGS. 4(a) through 4(h) are cross-sectional views of main portions of templates according to modifications.

### DETAILED DESCRIPTION

According to one embodiment, there is provided a template which includes a first region and a second region. The first region is provided with a first pattern of a plurality of recessed portions formed on a main surface of the template, and has a first thickness. The second region is provided with a second pattern of a plurality of recessed portions formed on the main surface of the template, and has a second thickness different from the first thickness. The second pattern is different from the first pattern in at least one of interval and dimension of the recessed portions.

### (Configuration of Template)

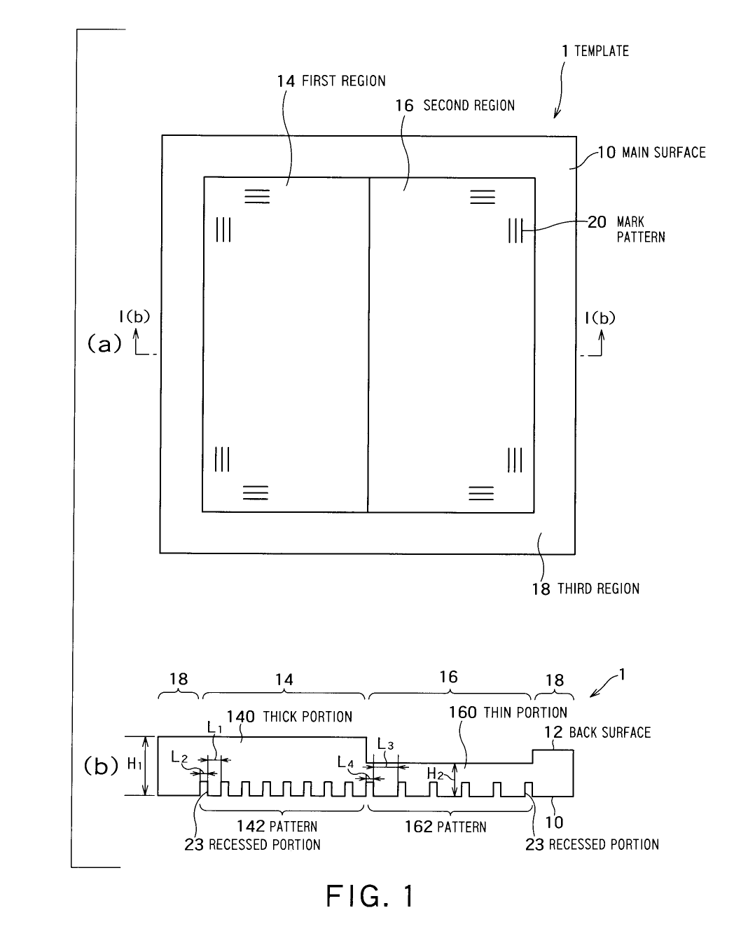

FIG. 1(a) is a plan view of a template according to an embodiment, and FIG. 1(b) is a cross-sectional view taken along the line I(b)-I(b) of FIG. 1(a). FIG. 1(a) illustrates the side of a main surface 10 of a template 1 on which patterns are formed. FIG. 1(b) illustrates a cross section taken along the line I(b)-I(b) of FIG. 1(a) such that the main surface 10 of the cross section is positioned on the lower side of FIG. 1(b).

The template 1 includes a first region 14 in which a pattern 142 as a first pattern made up of a plurality of recessed portions 22 is formed on the main surface 10 and which has a first thickness H₁, and a second region 16 in which a pattern 162 as a second pattern made up of a plurality of recessed portions 23, which differ from the recessed portions 22 of the pattern 142 in at least one of interval and dimension, is made on the main surface 10 and which has a second thickness H₂ different from that of the first thickness H₁.

In this embodiment, as illustrated in FIG. 1(b), a description is given of a case in which a dimension L₂ of the recessed portion 22 in the first region 14 is the same as a dimension L₄ of the recessed portion 23 in the second region 16, and an interval L₁ between the recessed portions 22 is different from an interval L₃ between the recessed portions 23 (i.e., L₂=L₄ and L₁≠L₃).

The template 1 may further include a third region 18 which is a region around the first and second regions 14 and 16. The template 1 is made of, for example, a Si-based substrate containing mainly Si. The shape of the template 1 as seen from the side of the main surface 10 is, for example, a 65 mm square.

In the first region 14, as illustrated in FIG. 1(b), a thick portion 140 is formed. Also in the second region 16, as illustrated in FIG. 1(b), a thin portion 160 is formed.

As illustrated in FIG. 1(b), the interval L₁ between the recessed portions 22 of the pattern 142 is narrower than the interval L₃ between the recessed portions 23 of the pattern 162. That is, the first region 14 is a region in which the pattern is dense (region of high pattern density) compared to the second region 16. The second region 16 is a region in which the pattern is sparse (region of low pattern density) compared to the first region 14.

In the thick portion 140, the thickness between the main surface 10 and a back surface 12 of the template 1 is H₁. The thickness H₁ in this embodiment is the same as the thickness of the third region 18. This thickness H₁ is, for example, 6 mm. The thick portion 140 is formed in a region in which the pattern is dense. It is to be noted that the thick portion 140 may have a thickness different from that of the third region 18.

In the thin portion 160, the thickness between the main surface 10 and the back surface 12 of the template 1 is H₂. This thickness H₂ is less than H₁. The thin portion 160 is formed in a region in which the pattern is sparse. The thickness H₂ is, for example, 1 mm.

The back surface 12 of the template 1 is formed by mechanical processing using a cutting machine, or formed by processing using sandblast, or the like.

As illustrated in FIG. 1(a), the first and second regions 14 and 16 have a plurality of mark patterns 20. The mark patterns 20 are used for optical alignment with a substrate on which a resist film to which a pattern is to be transferred is formed. It is to be noted that the mark patterns 20 may be formed in the third region 18.

The third region 18 is a region in which, for example, a chuck configured to hold the template 1 is placed. The chuck comes in contact with the template 1, and then produces a vacuum between the contacted portion and the template 1 to hold the template 1.

Hereinbelow, a description will be given of a method of manufacturing the template 1 according to this embodiment.

### (Template Manufacturing Method)

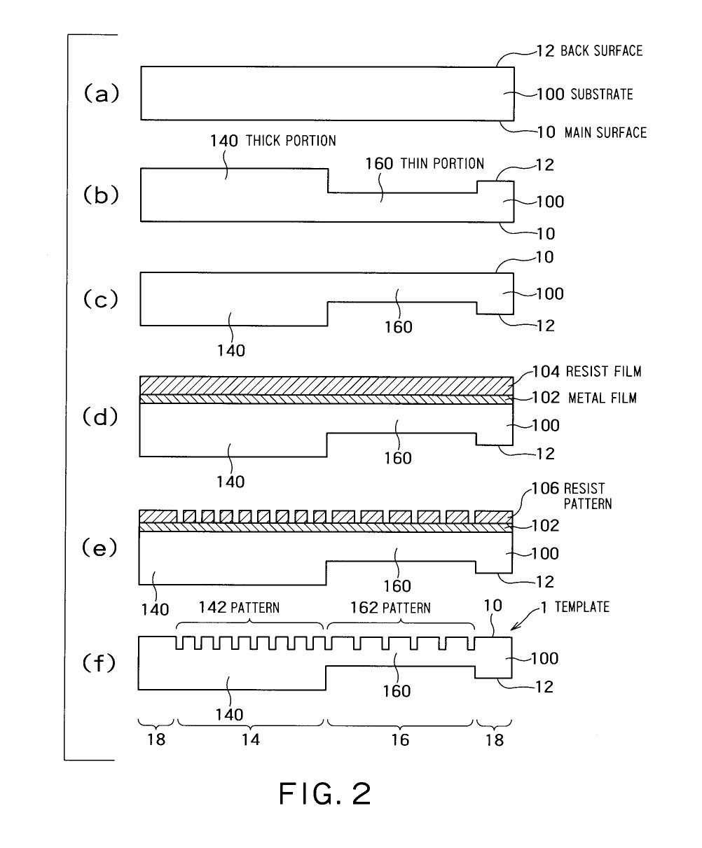

FIGS. 2(a) through 2(f) are process drawings of a template manufacturing method according to the embodiment. Initially, as illustrated in FIG. 2(a), a substrate 100, which is a Si-based substrate, is prepared. The thickness of the substrate 100 is the same as, for example, the first thickness H₁ at which the pattern 142 is formed. The substrate 100 includes the main surface 10 and the back surface 12 which are opposite to each other.

Next, as illustrated in FIG. 2(b), a cutting process of cutting a predetermined portion (e.g., a portion corresponding to the second region 16) of the back surface 12 to a predetermined depth from the back surface 12 is performed using a cutting machine or the like, so that the thin portion 160 is formed. It is to be noted that when the thickness of the thick portion 140 is different from that of the third region 18, at least one of the thick portion 140 and the third region 18 is processed using a cutting machine.

Specifically, initially, layout data of patterns to be formed on the template 1 is input to a cutting machine. The layout data may be stored in advance in the cutting machine, and may also be acquired from the outside. Subsequently, the cutting machine calculates a dense region and a sparse region based on the input layout data, and determines the layout of the back surface 12 based on the calculated sparse region and the dense region. The calculation of a dense region and a sparse region may be performed for each of blocks classified by function, such as a control unit and a storage unit. In addition, the layout of the back surface 12, instead of being calculated from the layout data, may be stored in advance in the cutting machine and may also be acquired from the outside. It is to be noted that while the layout of the back surface 12 is determined from two regions, a sparse region and a dense region, in this embodiment, the way of determining the layout of the back surface 12 is not limited to this. The two regions are divided into more regions, and the thickness of the template 1 may be varied stepwise. In addition, the cutting depth (the predetermined depth) can be determined depending on the pattern density formed in a region. For example, the lower the pattern density of a region, the deeper the region may be cut such that the thickness of the region is more decreased.

Next, as illustrated in FIG. 2(c), the substrate 100 is turned upside down.

Next, as illustrated in FIG. 2(d), a metal film 102, which will be a hard mask, is formed on the substrate 100 by a sputtering method or the like, and subsequently a resist film 104 is formed on the metal film 102 by a CVD (Chemical Vapor Deposition) method or the like. It is to be noted that the metal film 102 is made of, for example, chromium (Cr). In addition, the resist film 104 is, for example, a chemically amplified resist used for an electron-beam lithography method.

Next, as illustrated in FIG. 2(e), the resist film 104 is patterned by an electron-beam lithography method or the like, so that a resist pattern 106 is formed.

Next, the metal film 102 is etched with the resist pattern 106 used as a mask by a RIE (Reactive Ion Etching) method or the like, and the resist pattern 106 is removed.

Next, as illustrated in FIG. 2(f), the main surface 10 of the substrate 100 is etched with the patterned metal film 102 used as a mask by a RIE method or the like. By this etching, the pattern 142 made up of a plurality of recessed portions can be formed in the first region 14 including the thick portion 140 which has not been cut by the cutting process, and the pattern 162 made up of a plurality of recessed portions can also be formed in the second region 16 including the thin portion 160. The pattern 162 is larger in at least one of interval and dimension of the recessed portions than the pattern 142.

Thereafter, the metal film 102 is removed, so that the template 1 is obtained.

The foregoing template manufacturing method is a method of manufacturing the template 1 used for an imprint process. However, the foregoing method may be used as a method of manufacturing a parent template. The parent template has, for example, a reversed pattern in which the pattern of a child template used for an imprint process is reversed. A method of manufacturing a child template from a parent template is performed, for example, in the following way. Initially, the reversed pattern of the parent template is pressed against a mask film (such as a resist film) formed on the child template, so that the reversed pattern is transferred to the mask film. Next, using the mask film after the transfer as a mask, a hard mask film (such as a chromium film) is formed. Next, using the hard mask film as a mask, the main surface of the child template is etched, so that the child template is obtained. It is preferable that the back surface of the child template be formed before the transfer pattern of the parent template is transferred. One reason for this is that this prevents adverse effects on the pattern due to vibrations and the like caused by cutting with use of a cutting machine.

Hereinbelow, a description will be given of a semiconductor device manufacturing method using the template 1 manufactured by the foregoing template manufacturing method. The template 1 is assumed to be attached to a semiconductor manufacturing apparatus.

### (Semiconductor Device Manufacturing Method)

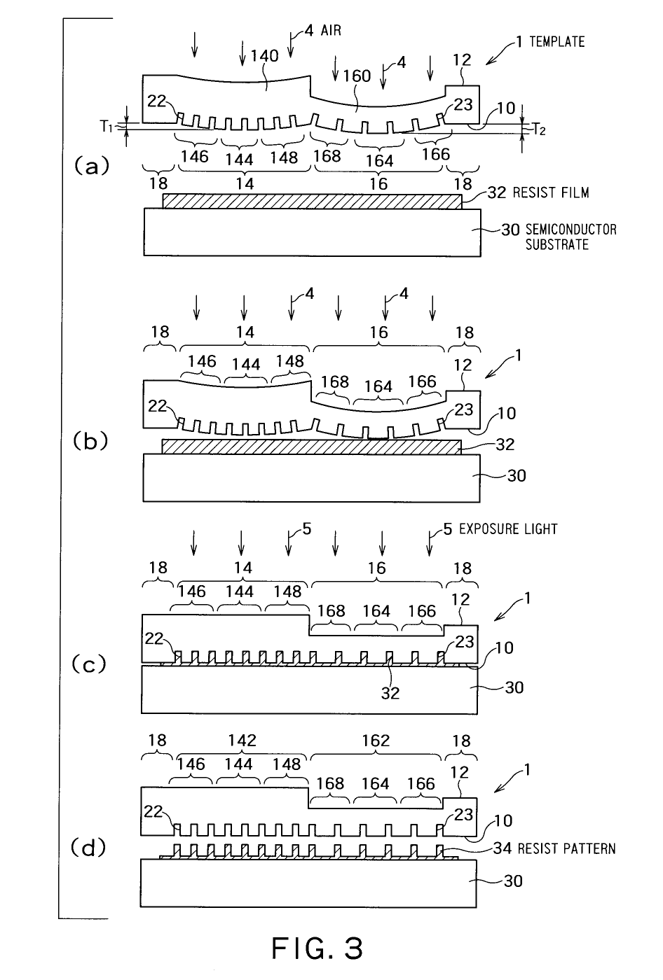

FIGS. 3(a) through 3(d) are process drawings of a semiconductor device manufacturing method according to the embodiment. In FIGS. 3(a) to 3(d), the recessed portions 22 and are depicted such that their shapes and the like are exaggerated for the purpose of illustrating flexures of the template 1.

Initially, a semiconductor substrate 30 on the surface of which a resist film 32 is formed is prepared. The resist film 32 is formed of, for example, an ultraviolet curing resist which is to be cured by irradiation with ultraviolet rays. This ultraviolet curing resist is a resist having high liquidity. It is to be noted that the resist film 32 may be formed on a film being processed which is formed on the semiconductor substrate 30.

Next, as can be seen from FIG. 3(a), the template 1 is disposed above the semiconductor substrate 30 such that the main surface 10 of the template 1 faces the resist film 32 of the semiconductor substrate 30.

Next, as illustrated in FIG. 3(a), air 4 is delivered to the side of the back surface 12 of the template 1. In the template 1, as illustrated in FIG. 3(a), the first and second regions 14 and 16 flex by the air 4.

In the first region 14, assuming that the pattern 142 is divided into a center portion 144 and peripheral portions 146 and 148 positioned around the center portion 144, the center portion 144 protrudes farthest from the main surface 10. A distance T₁ illustrated in FIG. 3(a) is a distance from the main surface 10 to the edge of the center portion 144. As illustrated in FIG. 3(a), the shape of the first region 14 on the side of the main surface 10 is a curved surface with the protruding center portion 144.

In the second region 16, assuming that the pattern 162 is divided into a center portion 164 and peripheral portions 166 and 168 positioned around the center portion 164, the center portion 164 protrudes farthest from the main surface 10. A distance T₂ illustrated in FIG. 3(a) is a distance from the main surface 10 to the edge of the center portion 164. As illustrated in FIG. 3(a), the shape of the second region 16 on the side of the main surface 10 is a curved surface with the protruding center portion 164. The distance T₂ has a value greater than that of the distance T₁ because the thickness of the thin portion 160 is less than that of the thick portion 140.

Here, one reason for causing the first and second regions 14 and 16 of the template 1 to flex is as follows. If the template 1 is pressed against the resist film 32 without causing the template 1 to flex, air becomes likely to be accumulated in the recessed portions 22 and 23 of the patterns 142 and 162. This makes it difficult to completely fill the recessed portions 22 and 23 with a resist. To overcome this difficulty, the patterns 142 and 162 are caused to flex for the recessed portions 22 and 23 to be curved. As a result, air is less likely to be accumulated in the recessed portions 22 and 23, which makes it easy to completely fill the recessed portions 22 and 23 with the resist.

Next, as illustrated in FIG. 3(b), the template 1 and the semiconductor substrate 30 are moved relative to each other to bring the template 1 and the resist film 32 into contact with each other. At this point, the flexure of the second region 16 is greater than that of the first region 14 (T₂>T₁), and therefore contact with the resist film 32 begins from the center portion 164 of the second region 16. Subsequently, the template 1 and the semiconductor substrate 30 are further moved relative to each other to bring the whole of the first and second regions 14 and 16 into contact with the resist film 32, so that the recessed portions 22 and 23 of the template 1 are filled with the resist.

Next, as illustrated in FIG. 3(c), after the recessed portions 22 and 23 of the template 1 have been filled with the resist, the resist film 32 is irradiated with exposure light 5 from the side of the back surface 12 of the template 1, so that the resist film 32 is cured. The exposure light 5 is, for example, ultraviolet rays.

Next, as illustrated in FIG. 3(d), the template 1 and the resist film 32 are separated from each other to form a resist pattern 34. Subsequently, the residual film left on the bottom surfaces of recessed portions of the resist pattern 34 is removed. Thereafter, with the remaining resist pattern 34 used as a mask, the semiconductor substrate 30 or a film being processed which is formed on the semiconductor substrate 30 is patterned, and passes through known processes, so that a desired semiconductor device is obtained.

Here, in cases where the thicknesses of the template 1 vary from the center toward the outer periphery, or from the outer periphery toward the center, regardless of the densities of patterns, a great force can be exerted on the transferred resist pattern 34 at the time of separation of the template 1 and the resist film 32. The great force arises from a force associated with movement of the template 1 and from a reaction force by which the template 1 attempts to return to its original shape. Due to the exerted great force, there is a high possibility of causing a defect in the resist pattern 34.

On the other hand, in cases where the template 1 is used in which the thick portion 140 and the thin portion 160 are formed in accordance with the densities of patterns as in this embodiment, when separation of the template 1 and the resist film 32 is made, flexures having amounts in accordance with the densities of patterns occur in the template 1. Due to the flexures, first, the peripheral portion 146 of the thick portion 140 and the peripheral portion 166 of the thin portion 160 are separated from the resist film 32 sequentially from one side surfaces of the recessed portions 22 and 23 (side surfaces close to the outer periphery of the template 1). Further, as the separation progresses, the peripheral portions 148 and 168 near the center of the template 1 are separated, prior to the center portions 144 and 164, from the resist film 32 sequentially from one side surfaces of the recessed portions 22 and 23 (side surfaces on the side of the boundaries of the first and second regions 14 and 16). As the separation further progresses, the center portions 144 and 164 are separated from the resist film 32 and, as a result, the template 1 is completely separated from the resist film 32. In such a manner, in the case of using the template 1 according to this embodiment, separation of the template 1 and the resist film 32 is not made at one time but is made gradually. Consequently, the force exerted on the resist pattern upon separation is small compared to the case of not forming the thick portion 140 and the thin portion 160. As a result, defect occurrence is suppressed as much as possible, so that the good resist pattern 34 is obtained.

In addition, the thicknesses of the template 1 vary in accordance with the densities of patterns, and therefore the reaction forces of the template 1 are also in accordance with the densities of patterns. For this reason, the speeds of separation vary in accordance with the densities of patterns, and therefore the good resist pattern 34 is obtained.

As described above, with the template 1 according to the embodiment, the defect in pattern shape can be suppressed. That is, according to the above template 1, separation of the template 1 and the cured resist film 32 is gradually made compared to the case of not forming the thick portion 140 and the thin portion 160. Therefore, the force required for separation becomes smaller, which suppresses the defect in pattern shape. Thus, the good resist pattern 34 can be obtained. In addition, according to the above template 1, the reaction forces of the template 1 are in accordance with the densities of patterns, and therefore the speeds of separation vary in accordance with the densities of patterns. Thus, it is possible to suppress the defect in pattern shape to obtain the good resist pattern 34.

With the above template 1, the recessed portions 22 and 23 are more likely to be completely filled with the resist film 32 compared to the case of not forming the thick portion 140 and the thin portion 160. This enables the good resist pattern 34 to be obtained. In addition, with the above template 1, the thick portion 140 and the thin portion 160 are formed, and therefore flexures having amounts in accordance with the densities of patterns occur in the template 1 to improve the speed of filling the resist film 32, so that the throughput of manufacturing semiconductor devices improves.

Moreover, with the above template 1, the good resist pattern 34 is obtained, and therefore the yield of semiconductor devices improves.

### (Modifications)

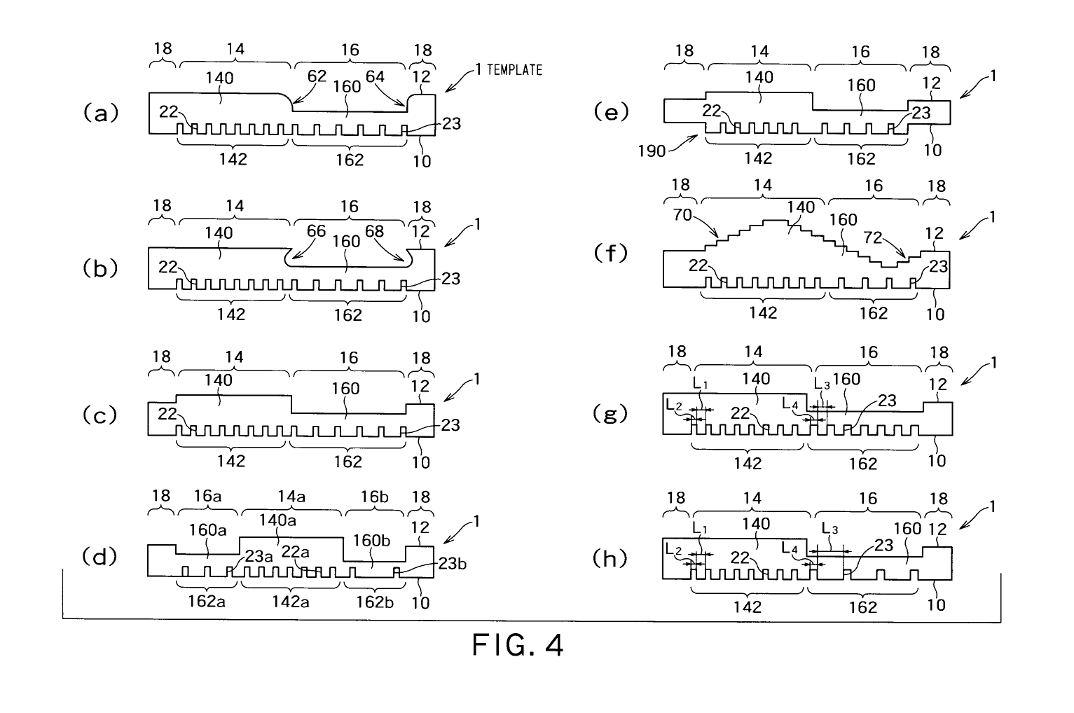

Modifications of the invention will be described below. FIGS. 4(a) through 4(h) are cross-sectional views of main portions of templates according to modifications. FIGS. 4(a) to 4(f) illustrate modifications in which, like in this embodiment, the dimension L₂ of the recessed portion 22 in the first region 14 is the same as the dimension L₄ of the recessed portion 23 in the second region 16, and the interval L₁ of the recessed portion 22 is different from the interval L₃ of the recessed portion 23 (i.e., L₂=L₄ and L₁≠L₃). FIG. 4(g) illustrates a modification in which the intervals of the recessed portions are the same, and the dimensions are different (i.e., L₂≠L₄ and L₁=L₃). FIG. 4(h) illustrates a modification in which both the dimensions and the intervals of the recessed portions are different (i.e., L₂≠L₄ and L₁≠L₃). These modifications have the same effects as the embodiment, and therefore differences between the modifications and the embodiment are mainly described below. Portions having the same functions and configurations as those of the embodiment are denoted below by the same reference characters, and descriptions thereof are omitted.

The template 1 illustrated in FIG. 4(a) includes a step portion 62 and a step portion 64. The step portion 62 is formed in an end on the side of the thin portion 160 of the thick portion 140, and has a curved surface connecting the back surface of the first region 14 and the back surface of the second region 16. The step portion 64 is formed in an end on the side of the thin portion 160 of the third region 18, and has a curved surface connecting the back surface of the third region 18 and the back surface of the second region 16. As can be seen from FIG. 4(a), in the cross section perpendicular to the main surface 10, the curved surface of the step portion 62 bulges from the first region 14 toward the second region 16, and the curved surface of the step portion 64 bulges from the third region 18 toward the second region 16.

The template 1 illustrated in FIG. 4(b) includes a step portion 66 and a step portion 68. The step portion 66 is formed in the inside of an end on the side of the thin portion 160 of the thick portion 140, and has a curved surface connecting the back surface of the first region 14 and the back surface of the second region 16. The step portion 68 is formed in the inside of an end on the side of the thin portion 160 of the third region 18, and has a curved surface connecting the back surface of the third region 18 and the back surface of the second region 16. As can be seen from FIG. 4(b), in the cross section perpendicular to the main surface 10, the curved surface of the step portion 66 bulges from the second region 16 toward the first region 14, and the curved surface of the step portion 68 bulges from the second region 16 toward the third region 18.

The template 1 illustrated in FIG. 4(c) is formed such that the thick portion 140 is thicker than the third region 18, and the thin portion 160 is thinner than the third region 18. That is, the thickness of the third region 18 is greater than that of the second region 16 and less than that of the first region 14.

The template 1 illustrated in FIG. 4(d) has regions 14a, 16a and 16b. As illustrated in FIG. 4(d), the region 18 is provided around the regions 14a, 16a and 16b.

The region 14a is a region near the center of the template 1 according to this modification, and a thick portion 140a is formed in this region. In the region 14a, a pattern 142a made up of a plurality of recessed portions 22a is formed on the main surface 10.

The region 16a is provided adjacent to the region 14a, and a thin portion 160a is formed in the region 16a. Formed in the region 16a is a pattern which is sparse compared to the pattern 142a of the region 14a. In the region 16a, a pattern 162a made up of a plurality of recessed portions 23a is formed on the main surface 10.

The region 16b is provided adjacent to the region 14a, and a thin portion 160b is formed in this region. Formed in the region 16b is a pattern which is sparse compared to the pattern 162a of the region 16a. In the region 16b, a pattern 162b made up of a plurality of recessed portions 23b is formed on the main surface 10.

As can be seen from FIG. 4(d), the thin portion 160a is formed thinner than the thick portion 140a, and the thin portion 160b is formed thinner than the thin portion 160a. That is, the lower pattern density the region has, the less thickness of the template the region has. In such a manner, the region is divided depending on the densities of patterns, and the thicknesses of the template 1 may vary from one resultant region to another.

The template 1 illustrated in FIG. 4(e) has a mesa structure 190 on the main surface 10. In the mesa structure 190, the pattern 142 and the pattern 162 which is sparser than the pattern 142 are formed. Like this embodiment, the thick portion 140 is formed in the first region 14, which is a dense region, and the thin portion 160 is formed in the second region 16, which is a sparse region.

The template 1 illustrated in FIG. 4(f) includes the thick portion 140 where the thickness gradually increases toward the center of the first region 14 and the thin portion 160 where the thickness gradually decreases toward the center of the second region 16. In the thick portion 140 and the thin portion 160, step portions 70 and 72 having step shapes are formed, respectively. It is to be noted that the shapes of the step portions 70 and 72 are not limited to step shapes, and may be slope shapes.

The template 1 illustrated in FIG. 4(g) is such that the interval L₁ between the recessed portions 22 of the pattern 142 in the first region 14 is equal to the interval L₃ between the recessed portions 23 of the pattern 162 in the second region 16, and the dimension L₄ of the recessed portion 23 is greater than the dimension L₂ of the recessed portion 22 (i.e., L₁=L₃ and L₂<L₄).

As described above, the resist on the substrate is filled into recessed portions, and passes through predetermined processes to form the resist pattern. At the time of separation of the cured resist and the template 1, the smaller the dimension of the recessed portion, the more the pattern defect is likely to be produced. Therefore, the template 1 according to this modification has the thick portion 140, at which the reaction force from the template 1 is smaller than that at the thin portion 160, in the first region 14 having the recessed portions 22 which are relatively small in dimension, and has the thin portion 160 in the second region 16 having the recessed portions 23 which are relatively large in dimension.

In the template 1 illustrated in FIG. 4(h), both the dimensions L₂ and L₄ and the intervals L₁ and L₃ between the recessed portions 22 of the first region 14 and the recessed portions 23 of the second region 16 are different from each other such that L₁<L₃ and L₂<L₄. The template 1 according to this modification has the thick portion 140, at which the reaction force from the template 1 is smaller than that at the thin portion 160, in the first region 14 having the recessed portions 22, and has the thin portion 160 in the second region 16 having the recessed portions 23.

It is to be noted that while the thickness of the sparse region is small whereas the thickness of the dense region is large in the foregoing embodiment and modifications, the thicknesses are not limited to these. For example, based on the viscosities, wettabilities and the like of a film on which a pattern is to be transferred and a remover, the thicknesses may be such that the thickness of the sparse region is large whereas the thickness of the dense region is small.

Also in the foregoing embodiment and modifications, both the recessed portions 22 and 23 have rectangular cross-sectional shapes. However, their cross-sectional shapes are not limited to these shapes, and may be different from each other.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A template comprising:
a first region being provided with a first pattern of a plurality of recessed portions formed on a main surface of the template, and having a first thickness; and
a second region being provided with a second pattern of a plurality of recessed portions formed on the main surface of the template, and having a second thickness different from the first thickness, the second pattern being different from the first pattern in at least one of interval and dimension of the recessed portions.

2. The template of claim 1, wherein
an interval between the recessed portions of the first pattern is narrower than an interval between the recessed portions of the second pattern, a thick portion having the first thickness is formed in the first region, and a thin portion having the second thickness less than the first thickness is formed in the second region.

3. The template of claim 2, wherein
the recessed portions of the first pattern have a dimension less than a dimension of the recessed portions of the second pattern.

4. The template of claim 3, wherein
the thickness of the thick portion gradually increases toward a center of the first region, and
the thickness of the thin portion gradually decreases toward a center of the second region.

5. The template of claim 2, further comprising:
a third region provided around the first and second regions.

6. The template of claim 5, further comprising:
a step portion being formed in an end on a side of the thin portion of the thick portion and having a curved surface connecting a back surface of the first region and a back surface of the second region, the curved surface bulging from the first region toward the second region in a cross section perpendicular to the main surface; and
a step portion being formed in an end on a side of the thin portion of the third region and having a curved surface connecting a back surface of the third region and the back surface of the second region, the curved surface bulging from the third region toward the second region in the cross section perpendicular to the main surface.

7. The template of claim 5, further comprising:
a step portion being formed in an inside of an end on a side of the thin portion of the thick portion and having a curved surface connecting a back surface of the first region and a back surface of the second region, the curved surface bulging from the second region toward the first region in a cross section perpendicular to the main surface; and
a step portion being formed in an inside of an end on a side of the thin portion of the third region and having a curved surface connecting a back surface of the third region and the back surface of the second region, the curved surface bulging from the second region toward the third region in the cross section perpendicular to the main surface.

8. The template of claim 5, wherein
the third region has a thickness greater than the thickness of the second region and less than the thickness of the first region.

9. The template of claim 2, wherein
the first and second patterns are formed in a mesa structure included on the main surface of the template.

10. A semiconductor device manufacturing method comprising:
preparing a semiconductor substrate with a resist film formed on a surface;
disposing the template of claim 2 above the semiconductor substrate such that the main surface of the template faces the resist film of the semiconductor substrate;
delivering air to a side of a back surface of the template for the air to cause the first and second regions to flex;
moving the template and the semiconductor substrate relative to each other to bring the template and the resist film into contact with each other;
after filling the recessed portions of the template with a resist, irradiating the resist film with exposure light from the side of the back surface of the template to cure the resist film; and
separating the template and the resist film from each other to form a resist pattern.

11. The template of claim 1, wherein
an interval between the recessed portions of the first pattern is equal to an interval between the recessed portions of the second pattern, and the recessed portions of the first pattern has a dimension less than a dimension of the recessed portions of the second pattern, and
a thick portion having the first thickness is formed in the first region, and a thin portion having the second thickness less than the first thickness is formed in the second region.

12. The template of claim 11, wherein
the thickness of the thick portion gradually increases toward a center of the first region, and
the thickness of the thin portion gradually decreases toward a center of the second region.

13. The template of claim 11, further comprising
a third region provided around the first and second regions.

14. A semiconductor device manufacturing method comprising:
preparing a semiconductor substrate with a resist film formed on a surface;
disposing the template of claim 11 above the semiconductor substrate such that the main surface of the template faces the resist film of the semiconductor substrate;
delivering air to a side of a back surface of the template for the air to cause the first and second regions to flex;
moving the template and the semiconductor substrate relative to each other to bring the template and the resist film into contact with each other;
after filling the recessed portions of the template with a resist, irradiating the resist film with exposure light from the side of the back surface of the template to cure the resist film; and
separating the template and the resist film from each other to form a resist pattern.

15. A template comprising:
a first region being provided near a center of the template, being provided with a first pattern of a plurality of recessed portions formed on a main surface of the template, and including a thick portion having a first thickness formed therein;
a second region being provided adjacent to the first region, being provided with a second pattern of a plurality of recessed portions formed on the main surface of the template, the second pattern being greater in interval between the recessed portions than the first pattern, and including formed therein a thin portion having a second thickness less than the first thickness; and
a third region being provided adjacent to the first region, being provided with a third pattern of a plurality of recessed portions formed on the main surface of the template, the third pattern being greater in interval between the recessed portions than the second pattern, and including formed therein a thin portion having a third thickness less than the second thickness.

16. The template of claim 15, further comprising:
a fourth region provided around the first to third regions.

17. The template of claim 15, wherein
the first to third patterns are formed in a mesa structure included on the main surface of the template.

18. A semiconductor device manufacturing method comprising:
preparing a semiconductor substrate with a resist film formed on a surface;
disposing the template of claim 15 above the semiconductor substrate such that the main surface of the template faces the resist film of the semiconductor substrate;
delivering air to a side of a back surface of the template for the air to cause the first and second regions to flex;
moving the template and the semiconductor substrate relative to each other to bring the template and the resist film into contact with each other;
after filling the recessed portions of the template with a resist, irradiating the resist film with exposure light from the side of the back surface of the template to cure the resist film; and
separating the template and the resist film from each other to form a resist pattern.

19. A template manufacturing method comprising:
preparing a substrate including a main surface and a back surface opposite to each other;
performing a cutting process of cutting a predetermined region of the back surface to a predetermined depth from the back surface, thereby forming a thin portion;
sequentially forming a metal film and a resist film on the main surface;
patterning the resist film to form a resist pattern;
etching the metal film with the resist pattern as a mask;
etching the main surface of the substrate with the patterned metal film as a mask to form a first pattern of a plurality of recessed portions in a first region including a thick portion not cut by the cutting process and form a second pattern of a plurality of recessed portions in a second region including the thin portion, the second pattern being smaller in at least one of interval and dimension of the recessed portions than the first pattern.

20. The template manufacturing method of claim 19, wherein
with a region having a low pattern density calculated based on layout data of a pattern to be formed on the template regarded as the predetermined region, the cutting process is performed.
